(19) United States
(12) Patent Application Publication
(10) Pub. No.: US 2024/0178112 A1
(43) Pub. Date: May 30, 2024

(54) SEMICONDUCTOR PACKAGE STRUCTURE AND METHOD OF FORMING THE SAME

(71) Applicant: MEDIATEK INC., Hsinchu City (TW)

(72) Inventors: Yu-Tung CHEN, Hsinchu City (TW); Kuo-Lung FAN, Hsinchu City (TW); Yen-Yao CHI, Hsinchu City (TW); Nai-Wei LIU, Hsinchu City (TW); Pei-Haw TSAO, Hsinchu City (TW)

(21) Appl. No.: 18/388,275

(22) Filed: Nov. 9, 2023

Related U.S. Application Data
(60) Provisional application No. 63/385,441, filed on Nov. 30, 2022.

(51) Int. Cl. H01L 23/498; H01L 23/31; H01L 23/532

(52) U.S. Cl. CPC H01L 23/49811; H01L 23/3128; H01L 23/49838; H01L 23/53238; H01L 23/53266

(57) ABSTRACT

A semiconductor package structure includes a semiconductor substrate, a conductive pad on the semiconductor substrate, and a passivation layer on the semiconductor substrate and the conductive pad. The passivation layer exposes a portion of the top surface of the conductive pad. The semiconductor package structure also includes a conductive adhesive layer on the conductive pad, and a dielectric layer on the passivation layer and the conductive adhesive layer. The dielectric layer exposes a portion of the conductive adhesive layer. The semiconductor package structure also includes a redistribution layer (RDL) structure on the dielectric layer and electrically connected to the conductive pad through the conductive adhesive layer. The semiconductor package structure also includes a bump structure over the RDL structure.

### CROSS REFERENCE TO RELATED APPLICATIONS

This application is based on, and claims priority of U.S. Provisional Application No. 63/385,441 filed on Nov. 30, 2022, the entirety of which is incorporated by reference herein.

### BACKGROUND OF THE INVENTION

### Field of the Invention

The present invention relates to a semiconductor package structure and a method of forming the same, and in particular to a semiconductor package structure having improved adhesion between components and a method of forming the same.

### Description of the Related Art

Integrated circuit (IC) devices are fabricated in a semiconductor wafer and divided into individual chips. Afterwards, those chips are assembled in package form to be used in electronic products. The semiconductor package provides a structure to support the chip and protect the chip from the environment. The semiconductor package also provides electrical connections to and from the chip.

Although existing semiconductor package have been adequate for their intended purposes, they have not been entirely satisfactory in all respects. For example, when an external circuitry such as a printed circuit board (PCB) is bonded to a semiconductor package structure, the bonding stress through solder balls to the bottom of a metal layer (such as a Cu redistribution layer) that is in direct contact with a conductive pad could cause delamination between the metal layer and the conductive pad. Therefore, there are still some problems to be overcome in regards to semiconductor package structure in the field of semiconductor integrated circuit technology.

### BRIEF SUMMARY OF THE INVENTION

Some embodiments of the present disclosure provide semiconductor package structures. An exemplary embodiment of a semiconductor package structure includes a semiconductor substrate, a conductive pad on the semiconductor substrate, and a passivation layer on the semiconductor substrate and the conductive pad. The passivation layer exposes a portion of the top surface of the conductive pad. The semiconductor package structure also includes a conductive adhesive layer on the conductive pad, and a dielectric layer on the passivation layer and the conductive adhesive layer. The dielectric layer exposes a portion of the conductive adhesive layer. The semiconductor package structure also includes a redistribution layer (RDL) structure on the dielectric layer and electrically connected to the conductive pad through the conductive adhesive layer. The semiconductor package structure also includes a bump structure over the redistribution layer (RDL) structure.

Some embodiments of the present disclosure provide a method of forming a semiconductor package structure. First, a semiconductor substrate is provided. A conductive pad is formed on the semiconductor substrate, and a passivation layer is formed on the semiconductor substrate and the conductive pad. The passivation layer exposes a portion of the top surface of the conductive pad. The method of forming the semiconductor package also includes forming a conductive adhesive layer on the conductive pad. The method of forming the semiconductor package also includes forming a dielectric layer on the passivation layer and the conductive adhesive layer, wherein the dielectric layer exposes a portion of the top surface of the conductive adhesive layer. The method of forming the semiconductor package also includes forming a redistribution layer (RDL) structure on the dielectric layer and electrically connected to the conductive pad through the conductive adhesive layer. The method of forming the semiconductor package also includes forming a bump structure over the redistribution layer (RDL) structure.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1A, FIG. 1B, FIG. 1C, FIG. 1D, FIG. 1E, FIG. 1F, FIG. 1G, FIG. 1H and FIG. 1I are cross-sectional views of intermediate stages of a method of forming a semiconductor package structure, in accordance with some embodiments of the present disclosure.

FIG. 2 is a cross-sectional view of an intermediate stage of a semiconductor package structure, in accordance with some embodiments of the present disclosure.

FIG. 3A, FIG. 3B, FIG. 3C, FIG. 3D and FIG. 3E are cross-sectional views of intermediate stages of a method of forming a semiconductor package structure, in accordance with some embodiments of the present disclosure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is determined by reference to the appended claims.

The inventive concept is described fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the invention.

The terminology used herein is for the purpose of describing particular embodiments only and is not intended to limit the invention. As used herein, the singular terms “a,” “an” and “the” are intended to include the plural forms as well, unless the context clearly indicates otherwise. Similarly, it should be understood that when an element such as a layer, region or substrate is referred to as being “on” another element, it can be directly on the other element or intervening elements may be present. In contrast, the term “directly” means that there are no intervening elements. It should be understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Furthermore, spatially relative terms may be used herein for ease of description to describe one element or feature's relationship to another element(s) or feature(s) as illustrated in figures. The spatially relative terms are intended to encompass different orientations of the device in use or operation in addition to the orientation depicted in the figures. It should be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same or similar reference numerals or reference designators denote the same or similar elements throughout the specification.

Some embodiments of the disclosure are described. It should be noted that additional procedures can be provided before, during, and/or after the stages described in these embodiments. Some of the stages that are described can be replaced or eliminated for different embodiments. Additional features can be added to the semiconductor package. Some of the features described below can be replaced or eliminated for different embodiments. Although some embodiments are discussed with procedures performed in a particular order, these procedures may be performed in another logical order.

According to some embodiments of the present disclosure, semiconductor package structures and methods of forming the same are described below to improve adhesion between components. In some embodiments, a conductive adhesive layer is formed between a conductive pad on a semiconductor substrate and a metal layer such as a redistribution layer (RDL). The contact area between the conductive pad and the metal layer can be enlarged by adding the conductive adhesive layer therebetween. According to the embodiments, the adhesion between the conductive pad and the conductive adhesive layer is stronger than the adhesion between the conductive pad and the metal layer, so as to prevent delamination between the conductive pad and the metal layer.

One of the methods of forming a semiconductor package structure in accordance with some embodiments of the present disclosure is provided below. It should be noted that the present disclosure is not limited to the exemplified package structures and forming methods provided herein. Those structures and processes described below are merely for providing examples of the configuration and fabrication of the semiconductor package.

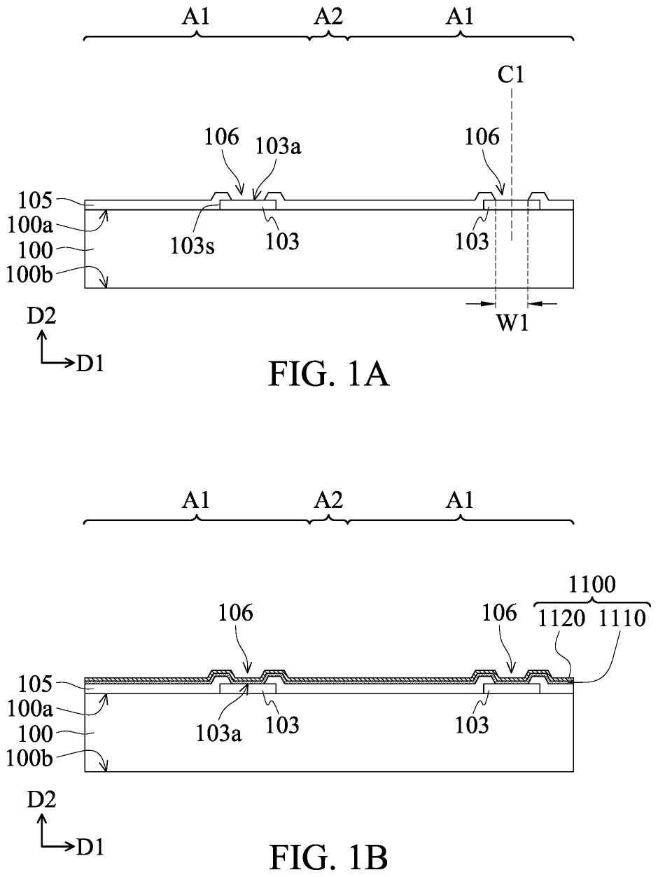

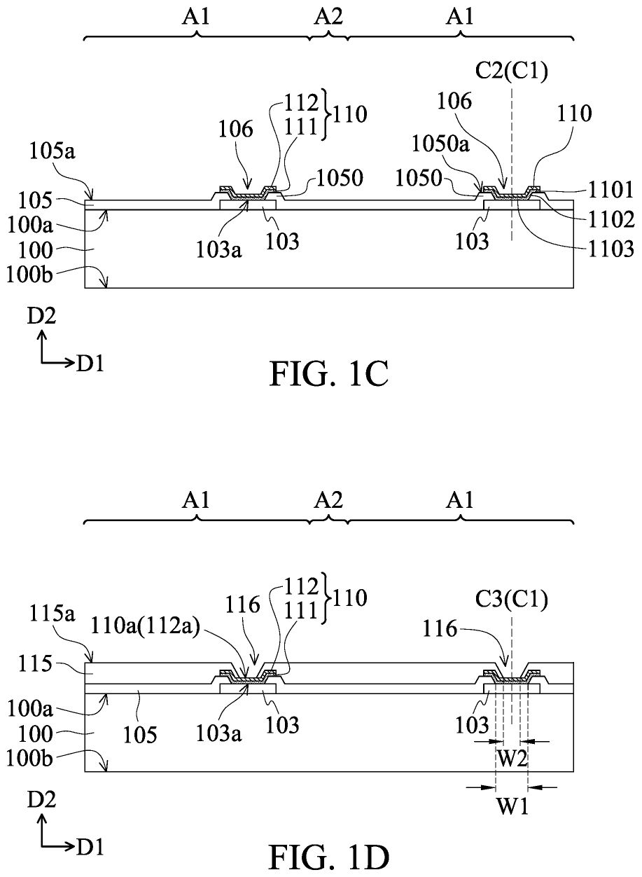

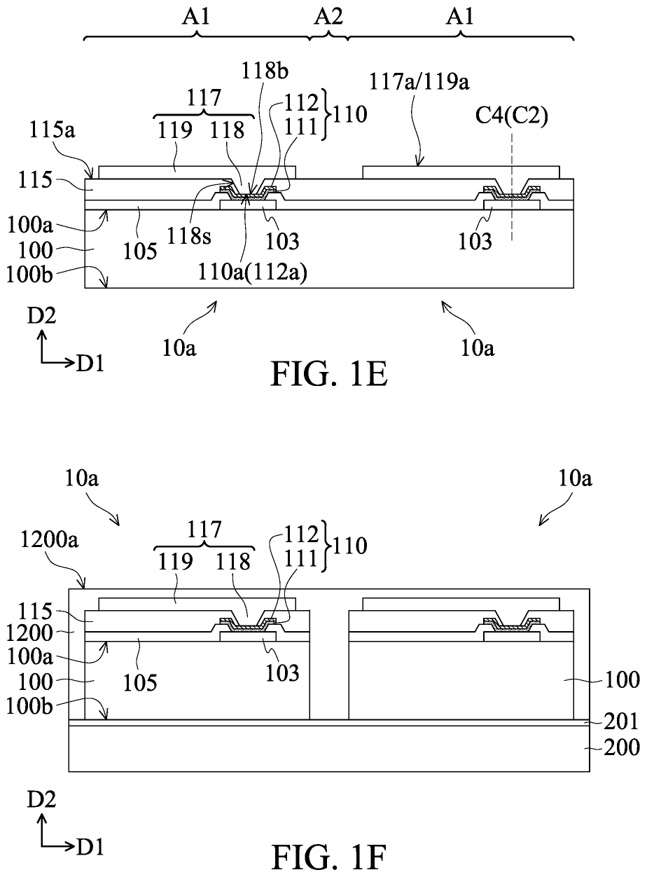

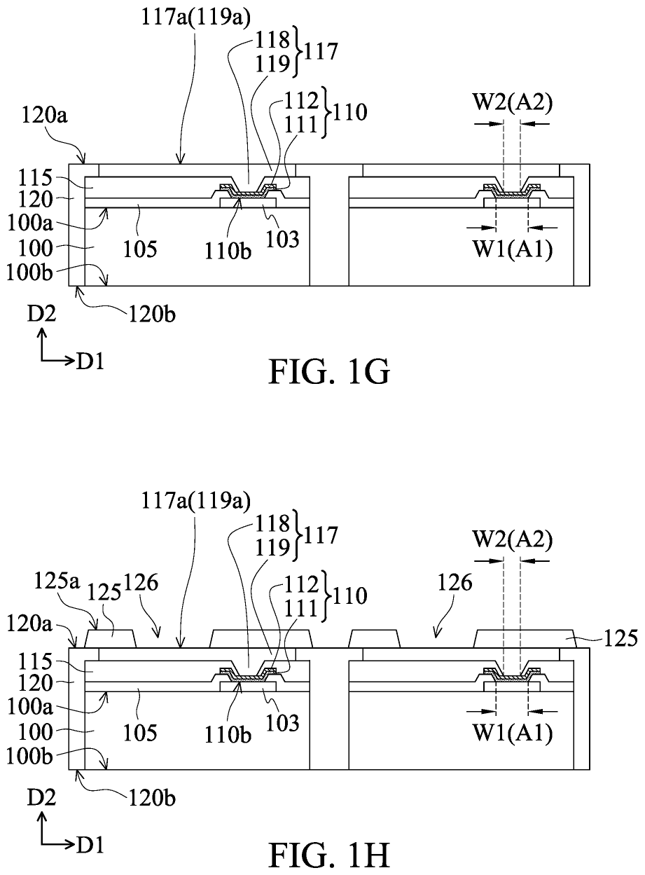

FIG. 1A, FIG. 1B, FIG. 1C, FIG. 1D, FIG. 1E, FIG. 1F, FIG. 1G, FIG. 1H and FIG. 1I are cross-sectional views of intermediate stages of a method of forming a semiconductor package structure, in accordance with some embodiments of the present disclosure. To simplify the diagram, only a portion of the semiconductor package structure is depicted in FIG. 1A-FIG. 1I.

Referring to FIG. 1A, a semiconductor substrate 100 is provided. In some embodiments, the semiconductor substrate 100 is a substrate of a semiconductor die. The semiconductor substrate 100 may include several chip regions A1 and a scribe line region A2 that surrounds the chip regions A1 and separates the adjacent chip regions A1 from each other. To simplify the diagram, only two adjacent chip regions A1 and a scribe line region A2 that separates these chip regions A1 are depicted herein for exemplification.

The semiconductor substrate 100 may be a silicon substrate or another semiconductor substrate. In some embodiments, the semiconductor substrate 100 is a silicon wafer so as to facilitate the wafer-level packaging process. The chip region A1 corresponds to a portion of the wafer after the wafer is diced along the scribe lines in the scribe line region A2 in the subsequent process.

In some embodiments, electrical circuitry (not shown) and device elements (not shown) may be formed within the semiconductor substrate 100, and the electrical circuitry may be any type of circuitry suitable for a particular application. For example, the electrical circuitry and device elements may include one or more N-type metal-oxide semiconductor (NMOS) devices and/or one or more P-type metal-oxide semiconductor (PMOS) devices, such as transistors, capacitors, resistors, diodes, photo-diodes, fuses, and the like, interconnected to perform one or more functions. The functions may be executed using various structures that include memory structures, processing structures, sensors, amplifiers, power distribution, input/output circuitry, or the like. Other electrical circuitry and device elements may be used as appropriate for a given application. Various processes are performed to form electrical circuitry and device elements, such as deposition, etching, implantation, photolithography, annealing, and/or other applicable processes. In some embodiments, electrical circuitry and device elements are formed in the semiconductor substrate 100 in a front-end-of-line (FEOL) process.

In addition, the semiconductor substrate 100 has the first surface 100a and the second surface 100b opposite the first surface 100a. An interconnection structure is formed on the first surface 100a, and the first surface 100a may be referred to as an active surface of the semiconductor substrate 100.

In some embodiments, several conductive pads 103 are formed on the semiconductor substrate 100, for example, on the first surface 100a of the semiconductor substrate 100, in each of the chip regions A1. The conductive pads 103 may be formed over an inter-metal dielectric (IMD) layer (not shown) in the semiconductor substrate 100. The conductive pads 103 are electrically connected to the device elements through various metallic lines and vias in the IMD layer. To simplify the diagram, only one conductive pad 103 in each chip region A1 is depicted in the drawings herein.

In some embodiments, the conductive pads 103 are configured for electrically coupling with bumps (such as the bump structures 140 in FIG. 1I) through conductive traces (such as the redistribution layer (RDL) structure 117 in FIG. 1E) to the conductive pads 103, so that the circuitry internal to the semiconductor substrate 100 connects with the circuitry external to the semiconductor substrate 100 from the conductive pad 103 to the bumps through the conductive traces.

In some embodiments, the conductive pads 103 can be made of gold (Au), silver (Ag), copper (Cu), aluminum (A1), tungsten (W), nickel (Ni), palladium (Pd) and/or alloys thereof. In some embodiments, the conductive pads 103 are formed by a plating method or another suitable method.

In addition, a passivation layer 105 is formed on the semiconductor substrate 100 and the conductive pads 103, in accordance with some embodiments of the present disclosure. The passivation layer 105 partially covers the conductive pads 103. As shown in FIG. 1A, the passivation layer 105 exposes a portion of the top surface 103a of each of the conductive pads 103. The conductive pad 132 and the passivation layer 105 are formed in a back-end-of-line (BEOL) process.

In some embodiments, the passivation layer 105 is configured for providing an electrical insulation and a moisture protection for the semiconductor substrate 100, so that the semiconductor substrate 100 is isolated from ambient environment. Thus, the passivation layer 105 can be referred to as a protective insulating layer.

In some embodiments, the passivation layer 105 is made of an inorganic material, such as spin-on glass (SOG), silicon oxide (SiOx), silicon nitride (SiNx), silicon oxynitride (SiON), silicon nitride (SiN) or a combination thereof, or another suitable insulating material. In some embodiments, the passivation layer 105 can be formed by using a vapor deposition, a spin coating process or another suitable process.

In addition, in this exemplified embodiment, the passivation layer 105 includes openings, such as first openings 106, above the conductive pads 103 for exposing the conductive pads 103, and thus for electrically connecting the conductive pads 103 with the circuitry external to the semiconductor substrate 100 through the conductive traces. Specifically, as shown in FIG. 1A, each of the first openings 106 exposes the portion of the top surface 103a of the conductive pad 103.

In some embodiments, each of the first openings 106 has a virtual central line C1 that divides the first opening 106 into two equal lateral distances in the first direction D1. The central line C1 extends in the second direction D2. The second direction D2 is different from (such as perpendicular to) the first direction D1. In some embodiments, the central line C1 of the first opening 106 can be aligned with the central line (not depicted) of the underlying conductive pad 103. However, the present disclosure is not limited thereto. In some other embodiments, the first opening 106 may be slightly offset from the underlying conductive pad 103.

In addition, in some embodiments, the first opening 106 has a first width W1 in the first direction D1. Sufficient width W1 of the first opening 106 enlarges the contact area between the conductive pad 103 and a conductive adhesive layer 110 (FIG. 1C).

According to some embodiments of the present disclosure, before a dielectric layer is deposited over the passivation layer 105 and the conductive pads 103, a conductive adhesive layer 110 (FIG. 1C) is formed on the conductive pads 103. Formation of the conductive adhesive layer 110 solves the problem of poor adhesion between the conductive pads 103 and a conductive portion (such as a redistribution layer (RDL)) that is formed subsequently. Accordingly, the conductive adhesive layer 110 prevents the delamination between the conductive pads and conductive portions on the conductive pads during the packaging processes and/or bonding processes (such as bonding a semiconductor package structure to a printed circuit board (PCB)).

The conductive adhesive layer 110 may be a single layer structure or a multilayer structure. In this exemplified embodiment, a conductive adhesive layer that includes two adhesive films is depicted for illustrations. However, the present disclosure is not limited thereto.

Referring to FIG. 1B, in some embodiments, a first adhesive film material 1110 is conformably formed on the passivation layer 105 and the exposed portions of the conductive pads 103. Specifically, the first adhesive film material 1110 covers the passivation layer 105 and the exposed portions of the top surfaces 103a of the conductive pads 103. In addition, the first adhesive film material 1110 that is deposited over the conductive pads 103 in the first openings 106 is formed as liner in the first openings 106 of the passivation layer 105.

Next, in some embodiments, a second adhesive film material 1120 is conformably formed on the first adhesive film material 1110. Specifically, the second adhesive film material 1120 covers the first adhesive film material 1110. The second adhesive film material 1120 is separated from the conductive pads 103 by the first adhesive film material 1110.

The first adhesive film material 1110 and the second adhesive film material 1120 include different conductive materials. In some embodiments, the first adhesive film material 1110 and the second adhesive film material 1120 include copper, titanium, tantalum, titanium nitride, tantalum nitride, the like, or a combination thereof. In one exemplified embodiment, the first adhesive film material 1110 is a titanium-based layer, and the second adhesive film material 1120 is a copper-based layer.

In addition, in some embodiments, the first adhesive film material 1110 and the second adhesive film material 1120 deposited by atomic layer deposition (ALD), sputtering, another physical vapor deposition (PVD) process, or the like. In one exemplified embodiment, the first adhesive film material 1110 and the second adhesive film material 1120 are formed by sputtering, so as to obtain the first adhesive film material 1110 and the second adhesive film material 1120 with high density.

In addition, in some embodiments, the first adhesive film material 1110 and the second adhesive film material 1120 are thin films. Accordingly, the profiles and formation of the material layers (such as the first dielectric layer 115 in FIG. 1D) that are laminated over a conductive adhesive layer (formed by patterning the first adhesive film material 1110 and the second adhesive film material 1120) would not be substantially changed, in accordance with some embodiments of the present disclosure.

In some embodiments, the thickness of the first adhesive film material 1110 is about 5 nm to about 200 nm. In some other embodiments, the thickness of the first adhesive film material 1110 is about 10 nm to about 100 nm. In some embodiments, the thickness of the second adhesive film material 1120 is about 5 nm to about 500 nm. In some other embodiments, the thickness of the second adhesive film material 1120 is about 20 nm to about 200 nm. In some embodiments, a total thickness of the first adhesive film material 1110 and the second adhesive film material 1120 is about 10 nm to about 700 nm. In some embodiments, a total thickness of the first adhesive film material 1110 and the second adhesive film material 1120 is about 30 nm to about 300 nm. It should be noted that the thicknesses of the first adhesive film material 1110 and the second adhesive film material 1120 of the present disclosure is not limited to the aforementioned exemplified numerical values. The actual numerical values of the thicknesses of the first adhesive film material 1110 and the second adhesive film material 1120 can be modified and determined according to the design conditions of the practical applications.

Next, referring to FIG. 1C, in some embodiments, the second adhesive film material 1120 and the first adhesive film material 1110 are patterned to form a second adhesive film 112 and a first adhesive film 111, respectively.

In some embodiments, photolithography and etching processes are performed to pattern the second adhesive film material 1120 and the first adhesive film material 1110, so as to remove a portion of the second adhesive film material 1120 and a portion of the first adhesive film material 1110. The remaining portion of the second adhesive film material 1120 is referred to as a second adhesive film 112. The remaining portion of the first adhesive film material 1110 is referred to as a first adhesive film 111. In this exemplified embodiment, the second adhesive film 112 and the first adhesive film 111 are collectively referred to as the conductive adhesive layer 110. The conductive adhesive layer 110 is formed on the conductive pads 103.

In addition, as shown in FIG. 1C, in some embodiments, the conductive adhesive layer 110 is in direct contact with the exposed portion of the top surface 103a of the conductive pads 103. The conductive adhesive layer 110 is configured as a liner in the first opening 106 of the passivation layer 105.

In addition, the conductive adhesive layer 110 has a symmetrical line C2 in the second direction D2. In some embodiments, the symmetrical line C2 may be aligned with the central line C1 of the first opening 106. However, the present disclosure is not limited thereto.

Specifically, in some embodiments, the conductive adhesive layer 110 includes wing portions 1101, sidewall portions 1102 and a bottom portion 1103. Portions of the conductive adhesive layer 110 that extend to the top surfaces 1050a of the protruding portions 1050 of the passivation layer 105 can be referred to as the wing portions 1101. The wing portions 1101 is physically separated from the conductive pads 103 by the sidewall portions 1102 and the bottom portion 1103. Portions of the conductive adhesive layer 110 that extend along the sidewalls of the first opening 106 of the passivation layer 105 can be referred to as the sidewall portions 1102. The portion of the conductive adhesive layer 110 that is formed in direct contact with and covers the top surface 103a of the conductive pads 103 can be referred to as the bottom portion 1103.

In addition, in some embodiments, a lateral dimension (in the first direction D1) of the conductive adhesive layer 110 corresponds to a lateral dimension (in the first direction D1) of the conductive pads 103. For example, the lateral edges of the wing portions 1101 of the conductive adhesive layer 110 may be aligned with or slightly protruding from the lateral edges 103s of conductive pads 103. It is not necessary to form the conductive adhesive layer 110 with a much larger width (in the first direction D1) than that of the conductive pads 103. However, the present disclosure is not limited thereto. It should be noted that, in some embodiments, the exemplified conductive adhesive layer 110 as shown in FIG. 1C are provided for illustrative purposes, and the embodiments of the present disclosure are not limited thereto.

Next, referring to FIG. 1D, a first dielectric layer 115 is formed on the passivation layer 105 and the conductive adhesive layer 110, in accordance with some embodiments of the present disclosure. The first dielectric layer 115 exposes a portion of the top surface 110a of the conductive adhesive layer 110. Specifically, the first dielectric layer 115 exposes a portion of the top surface 112a of the second adhesive film 112.

In some embodiments, the first dielectric layer 115 and the conductive adhesive layer 110 include different materials. The first dielectric layer 115 is an organic layer, such as a polymer layer. In some embodiments, the first dielectric layer 115 includes polybenzoxazole (PBO), polyimide (PI), benzocyclobutene (BCB), epoxy, a photo-sensitive material, another suitable polymer material, or a combination thereof.

In some embodiments, a dielectric material layer can be deposited by a spin coating process, laminating process, another suitable process or a combination thereof. Then, the dielectric material layer is patterned by photolithography and etching processes to remove portions of the dielectric material layer. For example, a photoresist layer (not shown) may be deposited over the dielectric material layer. The photoresist layer (not shown) may be patterned using photolithography to create a mask over the dielectric material layer. The dielectric material layer may be etched to expose a portion of the underlying conductive pads 103. The remaining portion of the dielectric material layer is referred to as the first dielectric layer 115.

In addition, in this exemplified embodiment, the first dielectric layer 115 includes openings, such as second openings 116, for exposing the conductive adhesive layer 110 on the conductive pads 103, and thus for electrically connecting the conductive pads 103 with the circuitry external to the semiconductor substrate 100 through the conductive traces.

In some embodiments, as shown in FIG. 1D, the first opening 106 is larger than the second opening 116. Each of the second openings 116 is located within the first opening 106 for exposing a smaller portion of the top surface 103a of the conductive pad 103. Specifically, in some embodiments, the first opening 106 has the first width W1 in the first direction D1, and the second opening 116 has the second width W2 in the first direction D1. The second width W2 is less than the first width W1.

In some embodiments, each of the second openings 116 has a virtual central line C3 that divides the second opening 116 into two equal lateral distances in the first direction D1. The central line C3 extends in the second direction D2. In some embodiments, the central line C3 of the second opening 116 can be substantially aligned with the central line C1 of the first opening 106. However, the present disclosure is not limited thereto. In some other embodiments, the second openings 116 may be slightly offset from the first opening 106.

In addition, in some embodiments, after the first dielectric layer 115 with the second openings 116 is formed, at least a portion of the conductive adhesive layer 110 is disposed between the first dielectric layer 115 and the passivation layer 105. For example, as shown in FIG. 1D, the wing portions 1101 of the conductive adhesive layer 110 are sandwiched between the first dielectric layer 115 and the passivation layer 105. Thus, the second opening 116 of the first dielectric layer 115 does not expose the wing portions 1101 of the conductive adhesive layer 110.

In addition, in some embodiments, after the first dielectric layer 115 is formed, the sidewall portions 1102 of the conductive adhesive layer 110 are completely covered by the first dielectric layer 115. For example, as shown in FIG. 1D, the sidewall portions 1102 of the conductive adhesive layer 110 are disposed between the first dielectric layer 115 and the passivation layer 105. That is, the second opening 116 of the first dielectric layer 115 does not expose the sidewall portions 1102 of the conductive adhesive layer 110, in accordance with some embodiments of the present disclosure.

Compared to the first dielectric layer 115, the first adhesive film 111 and the second adhesive film 112 are relatively thin, so that the first dielectric layer 115 that is laminated on the passivation layer 105 and the conductive adhesive layer 110 has a substantially flat top surface 115a, as shown in FIG. 1D. Specifically, in this exemplified embodiment, the portions of the top surface 115a of the first dielectric layer 115 that are right above the wing portions 1101 of the conductive adhesive layer 110 are still flat. Accordingly, although the conductive adhesive layer 110 is formed on the conductive pads 103 before the first dielectric layer 115 is formed over the conductive pads 103, the profiles and the fabrication processes of the material layers (such as the first dielectric layer 115 and other material layers formed subsequently) that are laminated over the conductive adhesive layer 110 would not be substantially changed, in accordance with some embodiments of the present disclosure.

Next, referring to FIG. 1E, in some embodiments, a redistribution layer (RDL) structure 117 is formed on the first dielectric layer 115. The redistribution layer (RDL) structure 107 is in direct contact with the exposed top surface 110a of the conductive adhesive layer 110. The redistribution layer (RDL) structure 117 is electrically connected to the conductive pads 103 through the conductive adhesive layer 110. The redistribution layer (RDL) structure 117 re-routes a path of a circuit from the conductive pads 103 to the circuitry external to the semiconductor substrate 100.

The redistribution layer (RDL) structure 117 may be a single layer structure or a multilayer structure. In some embodiments, the redistribution layer (RDL) structure 117 includes a conductive material such as gold, silver, copper, nickel, tungsten, aluminum, and/or alloys thereof.

Referring to FIGS. 1D and 1G, in this exemplified embodiment, the first width W1 of the first opening 106 is greater than the second width W2 of the second opening 116, as described above. Accordingly, after the redistribution layer (RDL) structure 117 is formed, the contact area A1 between the conductive adhesive layer 110 and the conductive pad 103 is greater than the contact area A2 between the redistribution layer (RDL) structure 117 and the conductive adhesive layer 110.

In some embodiments, the redistribution layer (RDL) structure 117 includes pillar portions 118 (that extend in the second direction D2) and a main portion 119 (that extends in the first direction D1). The pillar portions 118 are disposed in the second openings 116. For example, each pillar portion 118 fully fills the second opening 116, and the bottom surface 118b of the pillar portion 118 of the redistribution layer (RDL) structure 117 is in direct contact with the top surface 110a of the conductive adhesive layer 110, as shown in FIG. 1E.

In addition, in some embodiments, the sidewalls 118s and the bottom surface 118b of each of the pillar portions 118 of the redistribution layer (RDL) structure 117 are in contact with different material layers. For example, the bottom surface 118b of each of the pillar portions 118 is in contact with the conductive adhesive layer 110, and the sidewalls 118s of the pillar portion 118 is in contact with the first dielectric layer 115, as shown in FIG. 1E.

In addition, each of the pillar portions 118 of the redistribution layer (RDL) structure 117 has a symmetrical line C4 in the second direction D2. In some embodiments, the symmetrical line C4 of the pillar portion 118 is substantially aligned with the symmetrical line C2 of the underlying conductive adhesive layer 110. In other words, the lateral distances (in the first direction D1) between the sidewall portions 1102 of the conductive adhesive layer 110 and the sidewalls 118s of the pillar portion 118 are substantially equal to each other. That is, each of the pillar portions 118 of the redistribution layer (RDL) structure 117 is not offset from the underlying conductive adhesive layer 110. However, the present disclosure is not limited thereto. In some other embodiments, each of the pillar portions 118 of the redistribution layer (RDL) structure 117 may be slightly offset from the underlying conductive adhesive layer 110. That is, the symmetrical line C4 is offset from the symmetrical line C2.

According to the embodiments of the present disclosure, adhesion between the conductive pad 103 and the redistribution layer (RDL) structure 117 can be effectively improved by forming the conductive adhesive layer 110 between the conductive pad 103 and the pillar portions 118 of the redistribution layer (RDL) structure 117. That is, the adhesion between the conductive pad 103 and the conductive adhesive layer 110 (for example, the first adhesive film 111) is stronger than the adhesion between the conductive pad 103 and the redistribution layer (RDL) structure 117.

In one example, the conductive pads 103 are an aluminum pads, and the redistribution layer (RDL) structure 117 includes copper traces and vias. In a conventional package structure, delamination at the interface between the copper RDL structure 117 and aluminum conductive pads 103 may easily occur during the packaging processes and/or bonding processes (such as bonding a semiconductor package structure to a printed circuit board (PCB)). In some embodiments, a conductive adhesive layer 110 that includes a titanium film and a copper film (can be represented as “Ti/Cu film”) is disposed between the aluminum conductive pad 103 and the copper RDL structure 117. The adhesion between the aluminum conductive pad 103 and the Ti/Cu conductive adhesive layer 110 is stronger than the adhesion between the aluminum conductive pad 103 and the copper RDL structure 117. Accordingly, in some embodiments, the redistribution layer (RDL) structure 117 can be well attached to the conductive adhesive layer 110, so as to prevent the conventional delamination between the conductive pad 103 and the RDL structure 117.

In some embodiments, after the redistribution layer (RDL) structure 117 are formed, the chip regions A1 are separated from each other by dicing the scribe line region A2 to form semiconductor dies 10a with the redistribution layer (RDL) structure 117 thereon. The formed semiconductor dies may be system on chip (SOC) integrated circuit dies. The SOC integrated circuit die, for example, may include a logic die including a central processing unit (CPU), a graphics processing unit (GPU), a dynamic random access memory (DRAM) controller, or any combination thereof.

In some embodiments, a semiconductor die 10a includes a semiconductor substrate 100, at least one conductive pad 103 on the semiconductor substrate 100, a passivation layer 105 on the semiconductor substrate 100 and exposing a portion of the conductive pad 103, a conductive adhesive layer 110 on the conductive pad 103, a first dielectric layer 115 on the passivation layer 105 and exposing a portion of the conductive adhesive layer 110, and a redistribution layer (RDL) structure 117 over the semiconductor substrate 100.

Next, the semiconductor dies 10a can be mounted on another substrate (such as a carrier substrate) using a pick-and-place process, in accordance with some embodiments of the present disclosure.

Referring to FIG. 1F, in some embodiments, the semiconductor dies 10a are mounted onto a carrier substrate 200 using an adhesive layer 201. To simplify the diagram, only two semiconductor dies 10a mounted onto the carrier substrate 200 are depicted in the drawings herein.

The carrier substrate 200 may be made of silicon, glass, ceramic, or another suitable material. The carrier substrate 200 may be a semiconductor wafer, and therefore the carrier substrate 200 is sometimes referred to as a carrier wafer. The adhesive layer 201 may be a light-to-heat conversion (LTHC) material layer or includes another suitable material.

Next, in some embodiments, as shown in FIG. 1F, a protective material layer 1200 is formed over the carrier substrate 200 to cover the semiconductor dies 10a. Specifically, the protective material layer 1200 surrounds the semiconductor substrates 100, the passivation layers 105, the first dielectric layers 115 and the redistribution layer (RDL) structure 117 that are in direct contact with the conductive adhesive layers 110. Therefore, the semiconductor dies 10a are encapsulated by the protective material layer 1200. In some embodiments, the protective material layer 1200 can protects the semiconductor dies 10a from the environment, thereby preventing the semiconductor dies 10a in the subsequently formed semiconductor package structure from damage due to the stress, the chemicals and the moisture.

In some embodiments, the protective material layer 1200 may be a molding compound, which may include base material and filler particles in the base material. The base material may include a polymer, a resin, an epoxy, or the like. The base material may be a carbon-based polymer or an acrylic-based polymer. The filler particles may be the particles of a dielectric material(s) such as SiO₂, Al₂O₃, silica, the compound of iron (Fe), the compound of sodium (Na), or the like, and may have spherical shapes. In some embodiments, the protective material layer 1200 may be formed by a molding process, such as a compression molding, a transfer molding, or another suitable molding method.

In one example, the protective material layer 1200 (such as epoxy or resin) may be applied while substantially liquid, and then may be cured through a chemical reaction. In addition, the protective material layer 1200 may be a thermally cured polymer or an ultraviolet (UV) cured polymer. The protective material layer 1200 may be applied as a gel or malleable solid capable of being formed around the semiconductor dies 10a, and then may be cured through a thermal curing process or an UV curing process. The protective material layer 1200 may be cured with a mold (not shown).

Next, referring to FIG. 1G, in some embodiments, after the protective material layer 1200 is formed, the semiconductor dies 10a encapsulated by the protective material layer 1200 are de-attached from the carrier substrate 200. The carrier substrate 200 and the adhesive layer 201 are removed. The second surfaces 100b of the semiconductor substrates 100 are exposed.

In some embodiments, a de-attaching process is performed by exposing the adhesive layer 201 (shown in FIG. 1F) using a laser or UV light when the adhesive layer 201 is made of an LTHC material. The LTHC material may be decomposed due to generated heat from the laser or UV light, and hence the carrier substrate 200 is removed from the semiconductor dies 10a. Accordingly, the second surfaces 100b of the semiconductor substrates 100 can be exposed from the protective material layer 1200, as shown in FIG. 1G.

In some embodiments, after the carrier substrate 200 is removed by the de-attaching process, a planarization process such as a chemical mechanical polish/grinding (CMP) process or a mechanical grinding process is performed on the top surface 1200a of the protective material layer 1200 until the redistribution layer (RDL) structure 117 are exposed from the protective material layer 1200. In one example, the top surface 1200a of the protective material layer 1200 may be grinded by a chemical mechanical polishing (CMP) process or another suitable grinding process.

After the planarization process, the remaining portion of the protective material layer 1200 can be referred to as a molding layer 120, as shown in FIG. 1G. In some embodiments, the molding layer surrounds the semiconductor substrates 100, the passivation layers 105, the conductive adhesive layers 110, the first dielectric layers 115 and the redistribution layer (RDL) structure 117.

In addition, in some embodiments, after the planarization process is performed, the molding layer 120 has a planar top surface 120a and a planar bottom surface 120b that is opposite the top surface 120a. The top surface 120a of the molding layer 120 is coplanar with the top surfaces 117a of the redistribution layer (RDL) structure 117. The bottom surface 120b of the molding layer 120 is coplanar with the second surfaces 100b of the semiconductor substrates 100 after the carrier substrate 200 is de-attached from the semiconductor dies 10a.

Referring to FIG. 1H, in some embodiments, a second dielectric layer 125 is formed on the redistribution layer (RDL) structure 117, in accordance with some embodiments of the present disclosure. The second dielectric layer 125 exposes a portion of the top surface 117a of the redistribution layer (RDL) structure. Specifically, the second dielectric layer 125 exposes a portion of the top surface 119a of the main portion 119 (that extends in the first direction D1) of the second dielectric layer 125.

The second dielectric layer 125 and the first dielectric layer 115 may be made of the same materials or different materials. In some embodiments, the second dielectric layer 125 is an organic layer, such as a polymer layer. In some embodiments, the second dielectric layer 125 includes polybenzoxazole (PBO), polyimide (PI), benzocyclobutene (BCB), epoxy, a photo-sensitive material, another suitable polymer material, or a combination thereof.

In some embodiments, a dielectric material layer can be deposited by a spin coating process, laminating process, another suitable process or a combination thereof. Then, the dielectric material layer is patterned by photolithography and etching processes to remove portions of the dielectric material layer. For example, a photoresist layer (not shown) may be deposited over the dielectric material layer. The photoresist layer (not shown) may be patterned using photolithography to create a mask over the dielectric material layer. The dielectric material layer may be etched to expose a portion of the underlying redistribution layer (RDL) structure 117. The remaining portion of the dielectric material layer is referred to as the second dielectric layer 125.

In addition, in some embodiments, the second dielectric layer 125 includes openings, such as third openings 126, for exposing the redistribution layer (RDL) structure 117, and thus for electrically connecting the conductive pads 103 with the circuitry external to the semiconductor substrate 100. In this exemplified embodiment, a circuitry external to the semiconductor substrate 100 (such as a PCB) is electrically connected to the conductive pads 103 through a bump structure 140 (FIG. 1I), the redistribution layer (RDL) structure 117 and the conductive adhesive layer 110 on the conductive pads 103.

In addition, in some embodiments, the third opening 126 of the second dielectric layer 125 is laterally offset from the conductive adhesive layer 110, as shown in FIG. 1H. However, the present disclosure is not limited thereto. In some other embodiments, the third opening 126 of the second dielectric layer 125 may be substantially aligned with the conductive adhesive layer 110.

In addition, in some embodiments, the third opening 126 of the second dielectric layer 125 is larger than the second opening 116 of the first dielectric layer 115 (FIG. 1D) that receives the pillar portions 118 of the redistribution layer (RDL) structure 117. In some embodiments, the third opening 126 of the second dielectric layer 125 is larger than the first opening 106 of the passivation layer 105 (FIG. 1A) in which the conductive adhesive layer 110 is formed. However, the dimensions and positions of the third opening 126, the second opening 116 and the first opening 106 of the second dielectric layer 125 can be appropriately adjusted and arranged depending on the practical requirements of the application.

Next, referring to FIG. 1I, in some embodiments, after the second dielectric layer 125 with the third opening 126 is formed over the semiconductor substrate 100, a bump structure 140 is formed on the exposed portion of the top surface 117a of the redistribution layer (RDL) structure 117. In some embodiments, the bump structure 140 may include an under bump metallization (UBM) layer 141 and a solder portion 142. It should be noted that the configuration of the bump structure 140 illustrated in FIG. 1I is provided for exemplification, and the present disclosure is not limited thereto.

In some embodiments, an under bump metallization (UBM) layer 141 is formed on the exposed portion of the top surface 117a of the redistribution layer (RDL) structure 117 and a solder portion 142 is formed on the UBM layer 141. The solder portion 142 and the UBM layer 141 are collectively referred to as the bump structure 140. The bump structure 140 is electrically connected to the semiconductor substrate 100 through the redistribution layer (RDL) structure 117, the conductive adhesive layer 110 and the conductive pads 103.

In some embodiments, the UBM 141 provides a solderable surface which is exposed for receiving the solder portion 142 (such as a solder bump or another suitable conductive portion). The UBM 141 is electrically connected to the conductive pad 103 through the redistribution layer (RDL) structure 117 and the conductive adhesive layer 110. In one example, the UBM 141 has a flat bottom surface 141b, and the conductive adhesive layer 110 has a flat bottom surface 110b. As shown in FIG. 1I, an interface between the UBM 141 and the redistribution layer (RDL) structure 117 is flat and substantially parallel to an interface between the conductive adhesive layer 110 and the conductive pad 103.

In some embodiments, the UBM layer 141 may include a single layer or multiple layers. For example, the UBM layer 141 may include a barrier layer and a seed layer. To simplify the diagram, the UBM layer 141 including a single layer is depicted herein as an example.

In some embodiments, the UBM layer 141 may be made of one or more conductive materials, such as copper (Cu), copper alloy, aluminum (A1), aluminum alloy, tungsten (W), tungsten alloy, titanium (Ti), titanium alloy, tantalum (Ta) or tantalum alloy. In addition, in some embodiments, the UBM layer 141 may further includes a copper seed layer (not shown). In some embodiments, the solder portion 142 is a solder bump, solder ball, solder paste or etc.

In one example, an under bump metallization (UBM) material layer is formed on the redistribution layer (RDL) structure 117 by a suitable metal deposition operation, such as electro or electroless plating, physical vapor deposition (PVD) including sputtering, chemical vapor deposition (CVD), atomic layer deposition (ALD), thermal evaporation, and electron beam evaporation. Then, a photoresist layer (not shown) is formed over the under bump metallization (UBM) material layer and patterned to form openings to expose the desired portions of the top surface of the under bump metallization (UBM) material layer. A solder material is subsequently formed in the openings over under bump metallization (UBM) material layer. The solder material may be formed by a suitable metal deposition operation, including electro or electroless plating, physical vapor deposition (PVD) including sputtering, chemical vapor deposition (CVD), atomic layer deposition (ALD), thermal evaporation, and electron beam evaporation. In some embodiments, a seed layer (not shown) is deposited on the under bump metallization (UBM) material layer before the solder material is deposited. The photoresist layer is subsequently removed by using photoresist stripping or another suitable method. After the photoresist layer is removed, the under bump metallization (UBM) material layer is etched by using the solder portion 142 as a mask to form the UBM layer 141. In some embodiments, after removal of the photoresist layer, the solder portion 142 is reflowed to form a smooth, hemispherical shape as shown in FIG. 1I. In one example, the solder portion 142 is reflowed by heating the solder to a temperature at which it softens and flows.

In addition, in some other embodiments, one or more metal layers (not shown) can be further formed between the UBM layer 141 and solder portion 142. For example, a copper-based layer (not shown) may be formed on the UBM layer 141, and a metal pillar (not shown) that has lower solderability than copper may be formed between the copper-based layer and the solder portion 142. The metal pillar may include nickel, nickel alloys or another suitable material. Because the metal pillar has a lower solderability than the copper-based layer, solder flow down the side of the metal pillar during solder reflow can be inhibited.

In addition, in some embodiments, the bump structure 140 over the second dielectric layer 125 can be laterally offset from the pillar portion 118 and the conductive adhesive layer 110, as shown in FIG. 1I. However, the present disclosure is not limited thereto. In some other embodiments, the bump structure 140 may be substantially disposed right above the pillar portion 118 and the conductive adhesive layer 110.

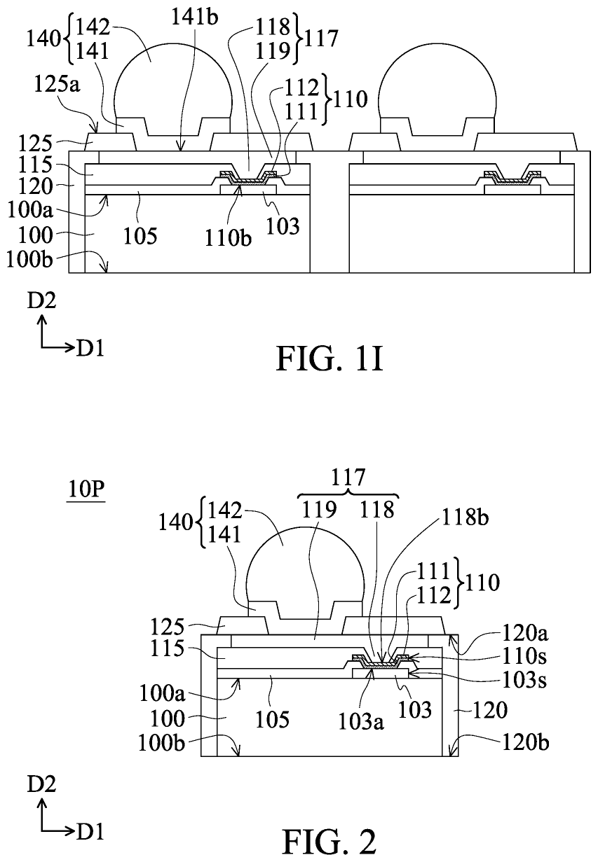

FIG. 2 is a cross-sectional view of an intermediate stage of a semiconductor package structure, in accordance with some embodiments of the present disclosure. In this exemplified embodiment, a semiconductor package structure 10P includes a semiconductor substrate 100, a conductive pad 103 on the semiconductor substrate 100 and a passivation layer 105 on the semiconductor substrate 100 and the conductive pad 103. The passivation layer 105 exposes a portion of the top surface 103a of the conductive pad 103. The semiconductor package structure 10P further includes a conductive adhesive layer 110 on the conductive pad 103, and a first dielectric layer 115 on the passivation layer 105 and the conductive adhesive layer 110. The first dielectric layer 115 exposes a portion of the conductive adhesive layer 110. The semiconductor package structure 10P further includes a redistribution layer (RDL) structure 117 on the first dielectric layer 115 and second dielectric layer 125. The RDL structure 117 is electrically connected to the conductive pad 103 through the conductive adhesive layer 110. The semiconductor package structure 10P further includes a bump structure 140 over the RDL structure 117.

In this exemplified embodiment, the wing portions 1101 of the conductive adhesive layer 110 are formed between the first dielectric layer 115 and the passivation layer 105. The lateral edges of the wing portions 1101 of the conductive adhesive layer 110 may be (but not limited to) aligned with or slightly protruding from the lateral edges 103s of conductive pads 103. According to the embodiments, the conductive adhesive layer 110 prevents the delamination due to the direct contact between the conductive pad and the conductive portion (such as RDL structure 117) on the conductive pad.

Although the semiconductor die 10a that has one conductive pad 103 is depicted in FIG. 1E to FIG. 1I, the semiconductor die 10a may include more conductive pad 103 (e.g., two, three, four, etc.). In addition, although a redistribution layer (RDL) structure 117 in the semiconductor package structure is depicted in FIG. 1E to FIG. 1I, the present disclosure is not limited thereto. More redistribution layer (RDL) structures can be formed in a semiconductor package structure, and the traces routing may be arranged depending on the practical requirements of the application. For example, several redistribution layer (RDL) structures can be formed to provide a semiconductor package structure with a fan-out structure. The conductive adhesive layer 110 in the embodiments can be applied to any types of the semiconductor package structure to prevent delamination between conductive pads and conductive portions (such as the RDL structures).

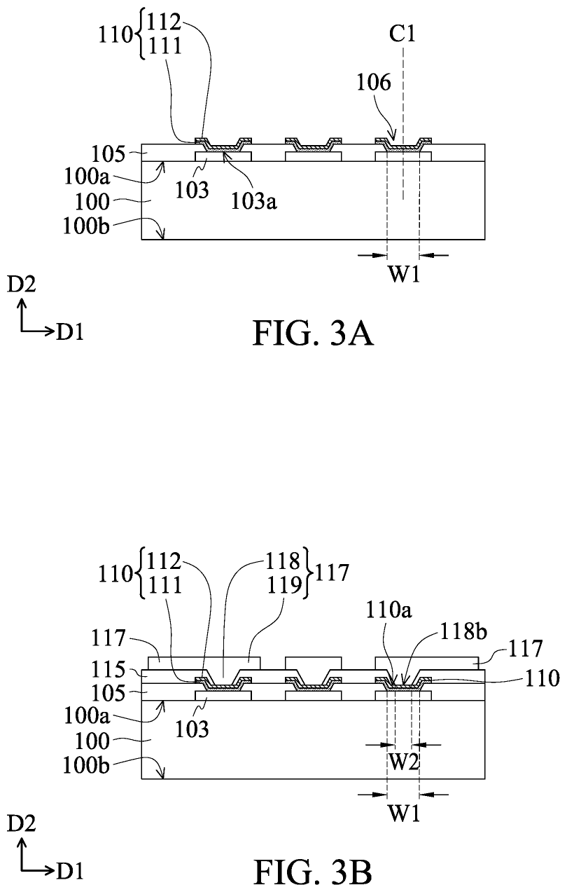

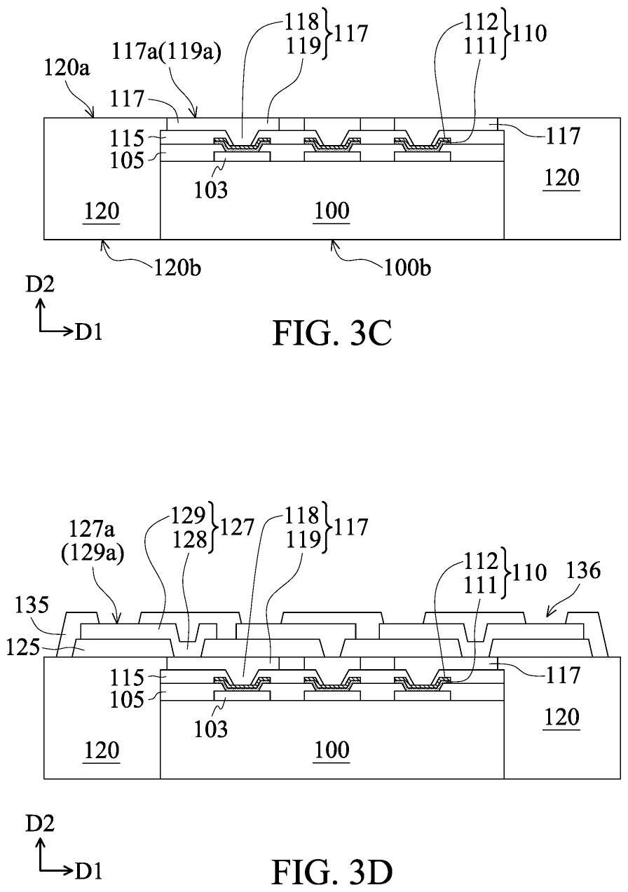

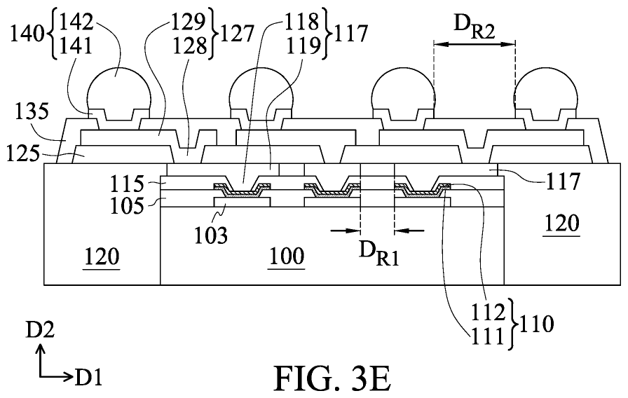

FIG. 3A, FIG. 3B, FIG. 3C, FIG. 3D and FIG. 3E are cross-sectional views of intermediate stages of a method of forming a semiconductor package structure, in accordance with some embodiments of the present disclosure. In this exemplary semiconductor package structure, three conductive pads 103 are formed on the semiconductor substrate 100, and two RDL structures are disposed over the semiconductor substrate 100 to provide a fan-out structure.

The same or similar reference numerals or reference designators denote the same or similar elements (such as components or layers) in FIG. 3A to FIG. 3E and FIG. 1A to FIG. 1I. Descriptions of elements in FIG. 3A to FIG. 3E of the embodiments hereinafter that are the same as or similar to those previously described with reference to FIG. 1A to 1I may be omitted for brevity.

Referring to FIG. 3A, in some embodiments, a semiconductor substrate 100 is provided. In some embodiments, electrical circuitry (not shown) and device elements (not shown) may be formed within the semiconductor substrate 100, and the electrical circuitry may be any type of circuitry suitable for a particular application. Two or more conductive pads may be formed on the semiconductor substrate 100. In this exemplified embodiment, three conductive pads 103 are formed on the semiconductor substrate 100, for example, on the first surface 100a (e.g. active surface) of the semiconductor substrate 100.

In some embodiments, the conductive pads 103 are configured for electrically coupling with bumps (such as the bump structures 140 in FIG. 3E) through conductive traces (such as the first RDL structure 117 and the second RDL structure 127 in FIG. 3E) to the conductive pads 103. In some embodiments, the conductive pads 103 can be made of gold (Au), silver (Ag), copper (Cu), aluminum (A1), tungsten (W), nickel (Ni), palladium (Pd) and/or alloys thereof. In some embodiments, the conductive pads 103 are formed by a plating method or another suitable method.

In addition, a passivation layer 105 is formed on the semiconductor substrate 100 and the conductive pads 103, in accordance with some embodiments of the present disclosure. The passivation layer 105 partially covers the conductive pads 103. For example, the passivation layer 105 exposes a portion of the top surface 103a of each of the conductive pads 103. As shown in FIG. 3A, the passivation layer 105 includes three first openings 106 that expose the conductive pads 103.

The passivation layer 105 may include an inorganic material, such as spin-on glass (SOG), silicon oxide (SiOx), silicon nitride (SiNx), silicon oxynitride (SiON), silicon nitride (SiN) or a combination thereof, or another suitable insulating material. The passivation layer 105 may be formed by depositing a passivation layer using a vapor deposition, a spin coating process or another suitable process, and then patterning the passivation layer to form the passivation layer 105 with several first openings 106.

According to some embodiments of the present disclosure, a conductive adhesive layer 110 (FIG. 1C) is formed on the conductive pads 103 before a dielectric layer (e.g. the first dielectric layer 115 in FIG. 3B) is deposited over the passivation layer 105 and the conductive pads 103. A circuitry internal to the semiconductor substrate 100 connects with another circuitry external to the semiconductor substrate 100 from the conductive pads 103 to the bumps structures 140 through the conductive adhesive layer 110 and the conductive traces of the RDL structures.

In some embodiments, the conductive adhesive layer 110 on the conductive pads 103 may include a second adhesive film 112 and a first adhesive film 111. The conductive adhesive layer 110 is in direct contact with the exposed portion of the top surface 103a of the conductive pads 103. The conductive adhesive layer 110 is configured as a liner in the first opening 106 of the passivation layer 105. The conductive adhesive layer 110 has extension portion (such as wing portions 1101 indicated in FIG. 1C) on the passivation layer 105.

The second adhesive film 112 and a first adhesive film 111 include different conductive materials, such as different metal-containing materials. In some embodiments, the first adhesive film 111 and the second adhesive film 112 include copper, titanium, tantalum, titanium nitride, tantalum nitride, the like, or a combination thereof. In one exemplified embodiment, the first adhesive film 111 is a titanium-based layer, and the second adhesive film 112 is a copper-based layer.

In one exemplified embodiment, a first adhesive film material and a second adhesive film material can be (but not limitedly) formed by sputtering, so as to obtain the adhesive film materials with high density. Then, the first adhesive film material and a second adhesive film material are patterned to form a second adhesive film 112 and a first adhesive film 111, respectively.

For the purpose of brevity, details of the configurations, the materials and the manufacturing methods of the semiconductor substrate 100, the conductive pads 103, the passivation layer 105 and the conductive adhesive layer 110 in FIG. 3A are similar to the above-mentioned descriptions referring to FIG. 1A to FIG. 1C, and will not be repeated here.

Next, referring to FIG. 3B, in some embodiments, a first dielectric layer 115 is formed on the passivation layer 105 and the conductive adhesive layer 110, in accordance with some embodiments of the present disclosure. The first dielectric layer 115 exposes a portion of the top surface 110a of the conductive adhesive layer 110. In some embodiments, the wing portions 1101 of the conductive adhesive layer 110 are sandwiched between the first dielectric layer 115 and the passivation layer 105. The first dielectric layer 115 may be an organic layer. For example, the first dielectric layer 115 may include polybenzoxazole (PBO), polyimide (PI), benzocyclobutene (BCB), epoxy, a photo-sensitive material, another suitable polymer material, or a combination thereof.

In some embodiments, a first RDL structure 117 is formed on the first dielectric layer 115 and electrically coupled to the conductive adhesive layer 110. For example, the pillar portions 118 of the first RDL structure 117 are in direct contact with the exposed top surface 110a of the conductive adhesive layer 110. Thus, the first RDL structure 117 is electrically connected to the conductive pads 103 through the conductive adhesive layer 110. The adhesion contact area between the conductive pad 103 and the pillar portions 118 of the first RDL structure 117 can be enlarged by adding the conductive adhesive layer 110 therebetween.

In addition, according to the embodiments, the adhesion between the conductive pad 103 and the conductive adhesive layer 110 is stronger than the adhesion between the conductive pad 103 and the first RDL structure 117, so as to prevent conventional delamination between the conductive pad and the metal trace of the RDL structure.

For the purpose of brevity, details of the configurations, the materials and the manufacturing methods of the first dielectric layer 115 and the first redistribution layer (RDL) structure 117 in FIG. 3B are similar to the above-mentioned descriptions referring to FIG. 1D and FIG. 1E, and will not be repeated here.

Next, referring to FIG. 3C, in some embodiments, a molding layer 120 is formed to surround the semiconductor substrates 100, the passivation layers 105, the conductive adhesive layers 110, the first dielectric layers 115 and the first RDL structure 117. In some embodiments, the top surface 120a of the molding layer 120 is coplanar with the top surfaces 117a of the first RDL structure 117. The bottom surface 120b of the molding layer 120 is coplanar with the second surfaces 100b of the semiconductor substrates 100.

For the purpose of brevity, details of the configurations, the materials and the manufacturing methods of the molding layer 120 in FIG. 3C are similar to the above-mentioned descriptions referring to FIG. 1F and FIG. 1G, and will not be repeated here.

Next, referring to FIG. 3D, in some embodiments, a second dielectric layer 125 is formed on the first RDL structure 117. The second dielectric layer 125 exposes portions of the top surface 117a of the first RDL structure 117. A second RDL structure 127 is formed on the second dielectric layer 125, and re-routes a path of a circuit from the conductive pads 103 to the circuitry external to the semiconductor substrate 100. The second RDL structure 127 may be a single layer structure or a multilayer structure, and may include gold, silver, copper, nickel, tungsten, aluminum, and/or alloys thereof. In this exemplified embodiment, the second RDL structure 127 includes pillar portions 128 (that extend in the second direction D2) and a main portion 129 (that extends in the first direction D1). The pillar portion 128 of the second RDL structure 127 is in direct contact with the first RDL structure 117. In addition, a third dielectric layer 135 is formed on the second RDL structure 127. The third dielectric layer 135 has openings 136 to expose portions of the top surface 127a (i.e. the top surface 129a of the main portion 129) of the second RDL structure 127. The third dielectric layer 135 and the second dielectric layer 125 may be made of the same dielectric material.

For the purpose of brevity, details of the configurations, the materials and the manufacturing methods of the second dielectric layer 125, the second RDL structure 127 and the third dielectric layer 135 in FIG. 3D are similar to the above-mentioned descriptions referring to FIG. 1H, and will not be repeated here.

Next, referring to FIG. 3E, in some embodiments, several bump structures 140 are formed on the exposed portions of the top surface 127a of the second RDL structure 127. Each of the bump structures 140 may include an under bump metallization (UBM) layer 141 and a solder portion 142. For the purpose of brevity, details of the configurations, the materials and the manufacturing methods of the bump structures 140 in FIG. 3E are similar to the above-mentioned descriptions referring to FIG. 1I, and will not be repeated here.

In this exemplified embodiment, as shown in FIG. 3E, the lateral distance D_{R2} (in the first direction D1) between the bump structures 140 may be longer than the lateral distance D_{R1} (in the first direction D1) between the traces of the first RDL structure 117 to achieve a fan-out structure.

According to some embodiments described above, the semiconductor package structures and the methods of forming the same achieve several advantages. In some embodiments, the contact area between a conductive adhesive layer and the conductive pad is greater than the contact area between the RDL structure and the conductive adhesive layer. Therefore, the contact area between the conductive pad and the RDL structure can be enlarged by adding the conductive adhesive layer therebetween. According to the embodiments, the adhesion between the conductive pad and the conductive adhesive layer is stronger than the adhesion between the conductive pad and the RDL structure, so as to prevent delamination between the conductive pad and the RDL structure. Therefore, the reliability of a semiconductor package structure having a conductive adhesive layer between the conductive pad and the RDL, in accordance with some embodiments, can be improved. In addition, the method of forming the semiconductor package structures of the embodiments is compatible with the existing processes, and do not include complicated and expensive manufacturing processes. Thus, it saves time to fabricating the semiconductor package structure and do not increase the manufacturing cost.

It should be noted that the details of the structures and fabrications of the embodiments are provided for exemplification, and the described details of the embodiments are not intended to limit the present disclosure. It should be noted that not all embodiments of the invention are shown. Modifications and variations can be made without departing from the spirit of the disclosure to meet the requirements of the practical applications. Thus, there may be other embodiments of the present disclosure which are not specifically illustrated. Furthermore, the accompanying drawings are simplified for clear illustrations of the embodiment. Sizes and proportions in the drawings may not be directly proportional to actual products. Thus, the specification and the drawings are to be regard as an illustrative sense rather than a restrictive sense.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a semiconductor substrate;
a conductive pad on the semiconductor substrate;
a passivation layer on the semiconductor substrate and the conductive pad, wherein the passivation layer exposes a portion of a top surface of the conductive pad;
a conductive adhesive layer on the conductive pad;
a dielectric layer on the passivation layer and the conductive adhesive layer, wherein the dielectric layer exposes a portion of a top surface of the conductive adhesive layer;
a redistribution layer (RDL) structure on the dielectric layer and electrically connected to the conductive pad through the conductive adhesive layer; and
a bump structure over the redistribution layer (RDL) structure.

2. The semiconductor package structure as claimed in claim 1, wherein the exposed top surface of the conductive adhesive layer is in direct contact with the redistribution layer (RDL) structure.

3. The semiconductor package structure as claimed in claim 1, wherein a contact area between the conductive adhesive layer and the conductive pad is greater than a contact area between the redistribution layer (RDL) structure and the conductive adhesive layer.

4. The semiconductor package structure as claimed in claim 1, wherein the passivation layer has a first opening that exposes the portion of the top surface of the conductive pad, and the conductive adhesive layer is configured as a liner in the first opening.

5. The semiconductor package structure as claimed in claim 4, wherein the dielectric layer has a second opening that exposes the portion of the top surface of the conductive adhesive layer, and the redistribution layer (RDL) structure comprises a pillar portion in the second opening.

6. The semiconductor package structure as claimed in claim 5, wherein the first opening is greater than the second opening.

7. The semiconductor package structure as claimed in claim 5, wherein a bottom surface of the pillar portion of the redistribution layer (RDL) structure is in direct contact with the top surface of the conductive adhesive layer.

8. The semiconductor package structure as claimed in claim 1, wherein a portion of the redistribution layer (RDL) structure that is in direct contact with the conductive adhesive layer has a first symmetrical line, the conductive adhesive layer has a second symmetrical line, and the first symmetrical line is aligned with the second symmetrical line.

9. The semiconductor package structure as claimed in claim 1, wherein the conductive adhesive layer includes a wing portion that extends on the passivation layer, and the wing portion of the conductive adhesive layer is disposed between the dielectric layer and the passivation layer.

10. The semiconductor package structure as claimed in claim 1, wherein the conductive adhesive layer comprises two or more metal layers.

11. The semiconductor package structure as claimed in claim 1, wherein the conductive adhesive layer comprises:
a first adhesive film on the conductive pad; and
a second adhesive film on the first adhesive film,
wherein the first adhesive film and the second adhesive film include different conductive materials.

12. The semiconductor package structure as claimed in claim 11, wherein an adhesion between the conductive pad and the first adhesive film is stronger than an adhesion between the conductive pad and the redistribution layer (RDL) structure.

13. The semiconductor package structure as claimed in claim 11, wherein the second adhesive film and the redistribution layer (RDL) structure include the same material.

14. The semiconductor package structure as claimed in claim 3, wherein the dielectric layer that is formed over the passivation layer and the conductive adhesive layer has a flat top surface.

15. The semiconductor package structure as claimed in claim 1, wherein the dielectric layer is a first dielectric layer, and the semiconductor package structure further comprises:
a second dielectric layer over the redistribution layer (RDL) structure,
wherein the second dielectric layer exposes a portion of a top surface of the redistribution layer (RDL) structure.

16. The semiconductor package structure as claimed in claim 15, wherein the redistribution layer (RDL) structure is a first redistribution layer (RDL) structure, and the semiconductor package structure further comprises:
a second redistribution layer (RDL) structure disposed on the second dielectric layer and electrically connected to the first redistribution layer (RDL) structure,
wherein the bump structure is disposed over the second redistribution layer (RDL) structure; and
wherein the bump structure is electrically connected to the semiconductor substrate through the second redistribution layer (RDL) structure, the first redistribution layer (RDL) structure, the conductive adhesive layer and the conductive pad.

17. The semiconductor package structure as claimed in claim 1, wherein the bump structure comprises:
an under-bump metallurgy (UBM) layer over the redistribution layer (RDL) structure; and
a solder portion over the UBM layer,
wherein the UBM layer is in direct contact with a top surface of the redistribution layer (RDL) structure, and the solder portion is electrically connected to the semiconductor substrate through the UBM layer, the redistribution layer (RDL) structure, the conductive adhesive layer and the conductive pad.

18. The semiconductor package structure as claimed in claim 1, further comprising:
a molding layer surrounding the semiconductor substrate, the passivation layer, the dielectric layer and the conductive adhesive layer.

19. A method of forming a semiconductor package structure, comprising:
providing a semiconductor substrate;
forming a conductive pad on the semiconductor substrate;
forming a passivation layer on the semiconductor substrate and the conductive pad, wherein the passivation layer exposes a portion of a top surface of the conductive pad;
forming a conductive adhesive layer on the conductive pad;
forming a dielectric layer on the passivation layer and the conductive adhesive layer, wherein the dielectric layer exposes a portion of a top surface of the conductive adhesive layer;
forming a redistribution layer (RDL) structure on the dielectric layer and electrically connected to the conductive pad through the conductive adhesive layer; and
forming a bump structure over the redistribution layer (RDL) structure.

20. The method of forming the semiconductor package structure as claimed in claim 19, wherein the exposed top surface of the conductive adhesive layer is in direct contact with the redistribution layer (RDL) structure.

21. The method of forming the semiconductor package structure as claimed in claim 19, wherein forming the conductive adhesive layer comprises:
forming a first adhesive film material on the passivation layer and the exposed portion of the top surface of the conductive pad; and
forming a second adhesive film material on the first adhesive film material, wherein the first adhesive film material and the second adhesive film material include different conductive materials; and
patterning the second adhesive film material and the first adhesive film material to form a second adhesive film and a first adhesive film, respectively,
wherein the second adhesive film and the first adhesive film collectively form the conductive adhesive layer.

22. The method of forming the semiconductor package structure as claimed in claim 21, wherein the first adhesive film material and the second adhesive film material are formed by sputtering.

23. The method of forming the semiconductor package structure as claimed in claim 21, wherein the dielectric layer that is formed over the passivation layer and the conductive adhesive layer has a flat top surface.

24. The method of forming the semiconductor package structure as claimed in claim 19, wherein a contact area between the conductive adhesive layer and the conductive pad is greater than a contact area between the redistribution layer (RDL) structure and the conductive adhesive layer.

25. The method of forming the semiconductor package structure as claimed in claim 19, wherein the formed passivation layer has a first opening that exposes the portion of the top surface of the conductive pad, and the conductive adhesive layer is configured as a liner in the first opening.

26. The method of forming the semiconductor package structure as claimed in claim 25, wherein the formed dielectric layer has a second opening that exposes the portion of the top surface of the conductive adhesive layer, and the first opening is larger than the second opening.

27. The method of forming the semiconductor package structure as claimed in claim 26, wherein after the dielectric layer with the second opening is formed, a central line of the second opening is aligned with a central line of the first opening.

28. The method of forming the semiconductor package structure as claimed in claim 21, wherein after the dielectric layer is formed, a wing portion of the conductive adhesive layer that extends on the passivation layer is disposed between the dielectric layer and the passivation layer.

29. The method of forming the semiconductor package structure as claimed in claim 21, wherein after the redistribution layer (RDL) structure is formed, the method further comprises:
forming a molding layer surrounding the semiconductor substrate, the passivation layer, the dielectric layer and the conductive adhesive layer.

30. The method of forming the semiconductor package structure as claimed in claim 21, wherein the dielectric layer is a first dielectric layer, and before forming the bump structure, the method further comprises:
forming a second dielectric layer on the first dielectric layer and the redistribution layer (RDL) structure,
wherein the second dielectric layer exposes a portion of a top surface of the redistribution layer (RDL) structure, and
wherein the bump structure is formed on the exposed portion of the top surface of the redistribution layer (RDL) structure.
